(19) United States
(12) Patent Application Publication
(10) Pub. No.: US 2019/0315231 A1
(43) Pub. Date: Oct. 17, 2019

(54) System and Method for Monitoring Resistor Life

(71) Applicants: Gabriel E. Widmer, West Lafayette, IN (US); Michael Joseph Mattingly, West Lafayette, IN (US)

(72) Inventors: Gabriel E. Widmer, West Lafayette, IN (US); Michael Joseph Mattingly, West Lafayette, IN (US)

(73) Assignee: Dayton-Phoenix Group, Inc., Dayton, OH (US)

(21) Appl. No.: 15/955,200

(22) Filed: Apr. 17, 2018

(51) Int. Cl. B60L 3/00; B60L 7/02; B61L 15/00; G01R 31/00; G01N 25/00

(52) U.S. Cl. CPC B60L 3/0076; B60L 7/02; B61L 15/009; B60L 2200/26; G01R 31/008; G01N 25/00; B61L 15/0081

(57) ABSTRACT

A system for monitoring a useful life of an insulation component of a braking resistor includes a sensor that can be embedded below an outer surface of the insulation component to measure a temperature of the insulation component; and a controller connected to receive a signal from the sensor indicative of the measured temperature of the insulation component, and programmed to compare the measured temperature of the insulation component to a predetermined threshold activation temperature for the insulation component, decrement from a predetermined useful life value for the insulation component a life depreciation value assigned to the measured temperature to determine a remaining life value of the insulation component if the measured temperature of the insulation component is greater than the threshold activation temperature, compare the remaining life value to an end-of-life value for the insulation component, and generate a warning signal if the remaining life value is at or below the end-of-life value.

### TECHNICAL FIELD

This disclosure pertains to systems and methods for monitoring the useful life of a device, and more particularly, to systems and methods for monitoring the useful life of the insulation component of a braking resistor subject to thermal degradation.

### BACKGROUND

In a diesel-electric locomotive, a diesel engine drives either a direct current (DC) generator or an alternating current (AC) alternator-rectifier that powers electric traction motors that turn the wheels of the locomotive. Diesel-electric locomotives use dynamic braking to slow or stop. This type of dynamic braking is known as rheostatic braking. Rheostatic braking systems also may be used in forklifts, streetcars, mining trucks, maintenance of way machinery, transit vehicles, and the like.

With dynamic or rheostatic braking, the electric power generated by the diesel engine to the electric traction motors is switched off. The traction motors instead use the rotation of the wheels from movement of the locomotive on the tracks to turn the rotors of the traction motors, thereby using the kinetic energy of the moving locomotive to generate electricity. This electricity may be directed to braking grids, also called dynamic braking grids, which are banks of resistors in the form of flat metal plates that heat up when the electric current passes through them, thereby putting a load on the traction motors. Generating this heat energy causes the locomotive wheels attached to the traction motors to resist rotation, thus slowing the locomotive.

A single locomotive may use several dynamic braking grids. Large fans are placed in the locomotive engine compartment, or other location in the locomotive, to direct cooling air across the resistor elements of the dynamic braking grids to protect the resistor elements from heat damage. Vehicles that use dynamic braking often have a backup braking system in the form of a friction braking system. A friction braking system may include air brakes, which are used automatically whenever the power supply connection is lost.

One type of dynamic braking grid resistor includes a rectangular frame made of a molded insulation, such as a resin impregnated with fiberglass. The resistor elements, in the form of flat plates, are surrounded by and attached to the frame. The plates are arranged spaced apart and parallel to each other within the frame. The resistor elements are connected in series to form a continuous electrical circuit within the braking grid. During dynamic braking, the grid plates may reach temperatures of up to 760° C. (1400° F.).

Continual exposure to high ambient temperatures during service, which may be on the order of 300° C. to 500° C. (572° F. to 932° F.), gradually breaks down the insulation of the frame component of the dynamic braking grid resistor. This breaking down typically manifests itself in a loss of the resin binder, which reduces the strength of the insulation. When the insulation supporting the braking grid resistor elements reaches, for example 50% of its strength, it is considered to have reached its—and consequently the resistor's—end of life, and the resistor must be replaced.

It is necessary to replace dynamic braking grid resistors before their insulation reaches its end of life, but at present there is no system for determining the life remaining in resistor insulation. Resistor replacement is made after a visual inspection, which must be performed during engine maintenance in the railyard. Since visual inspection is a subjective assessment that is somewhat arbitrary, it may result in replacement of dynamic braking grid resistors well in advance of their useful lives, which would result in increased cost of operation. Similarly, not replacing resistors that are near the end of their useful lives may result in resistor failures, unexpected machine or locomotive downtime, and loss of machine or locomotive efficiency and/or productivity.

Accordingly, there is a need for a system and method for accurately and consistently determining when the insulation component of a dynamic braking grid resistor has reached its useful life. There is also a need for a system and method for accurately and consistently determining the remaining useful life of the insulation component of a dynamic braking grid resistor. Such a system preferably should provide the useful life information without a user having to visually inspect the dynamic braking grid resistors of a resistor grid.

### SUMMARY

The present disclosure is directed to a system and method for monitoring the useful life of a dynamic braking grid resistor, and in an exemplary embodiment, the end-of-life of the braking grid resistor insulation, which does not require subjective visual inspection of the resistor. In other embodiments, the disclosed method and system not only provide an end-of-life alarm, but a continual or on-demand readout of the remaining life of a braking grid resistor, which facilitates efficient scheduling of maintenance.

In an exemplary embodiment, the system includes a sensor, such as a thermocouple, thermistor, or other resistance-temperature detector that is embedded in the resistor insulation. The temperature of the insulation is measured in time increments (e.g., 5 or 10 seconds) and stored. A controller uses an algorithm to adjust the measured temperature of the insulation to arrive at a surface temperature of the insulation. In an embodiment, when the equivalent of 400° C. (752° F.) for 2000 hours is reached, the system displays or sends an alert that the resistor has reached end of life and should be replaced.

In other embodiments, the recording of temperatures is triggered when the resistor insulation surface temperature exceeds 60° C. (140° F.). Different values may be assigned for time increments in which the surface temperature is less than 400° C., in 1° C. steps, and the time increment measurements summed to arrive at a percent of end of life remaining. This system and method also may be useful to determine end-of-life for other electrical components, such as transformers and electrical contactors. Temperature ranges may be different based on materials and application.

In one particular embodiment, a system for monitoring a useful life of an insulation component of a braking resistor includes a sensor that can be embedded below an outer surface of the insulation component of the resistor to measure a temperature of the insulation component; a controller connected to receive a signal from the sensor indicative of the measured temperature of the insulation component and programmed to compare the measured temperature of the insulation component to a predetermined threshold activation temperature for the insulation component, decrement from a predetermined useful life value for the insulation component a life depreciation value assigned to the measured temperature to determine a remaining life value of the insulation component if the measured temperature of the insulation component is greater than the threshold activation temperature, compare the remaining life value to a predetermined end-of-life value for the insulation component, and generate a warning signal if the remaining life value is at or below the predetermined end-of-life value. The system also can provide a discrete life value, such as percent of life left.

In another embodiment, a method for monitoring a useful life of an insulation component of a braking resistor includes measuring a temperature of the insulation component with a sensor; receiving a signal from the sensor indicative of a temperature of the insulation component by a controller; and the controller comparing the measured temperature of the insulation component to a predetermined threshold activation temperature for the insulation component, decrementing from a predetermined useful life value for the insulation component a life depreciation value assigned to the measured temperature to determine a remaining life value of the insulation component if the measured temperature of the insulation component is greater than the threshold activation temperature, comparing the remaining life value to an end-of-life value for the insulation component, and generating a warning signal if the remaining life value is at or below the predetermined end-of-life value.

In yet another embodiment, a system for monitoring a useful life of a test object includes a sensor that can be attached to the test object to measure a temperature of the test object; a controller connected to receive a signal from the sensor indicative of the measured temperature of the test object, and programmed to compare the measured temperature of the test object to a predetermined threshold activation temperature for the test object, decrement from a predetermined useful life value for the test object a life depreciation value assigned to the measured temperature to determine a remaining life value of the test object if the measured temperature of the test object is greater than the threshold activation temperature, compare the remaining life value to a predetermined end-of-life value for the test object, and generate a warning signal if the remaining life value is at or below the predetermined end-of-life value for the test object.

Other objects and advantages of the disclosed system and method for monitoring resistor life will be apparent from the following description, the accompanying drawings, and the appended claims.

### BRIEF DESCRIPTION OF THE DRAWINGS

FIG. 1 is a schematic representation of the disclosed system for monitoring resistor life, used to measure the remaining useful life of a resistor in a locomotive dynamic braking grid;

FIG. 2 is a schematic representation of the system of FIG. 1, used to measure the remaining useful lives of a plurality of resistors making up a dynamic braking grid in a locomotive; and

FIGS. 3 and 4 combine to show a flow chart of a method for monitoring resistor life.

### DETAILED DESCRIPTION

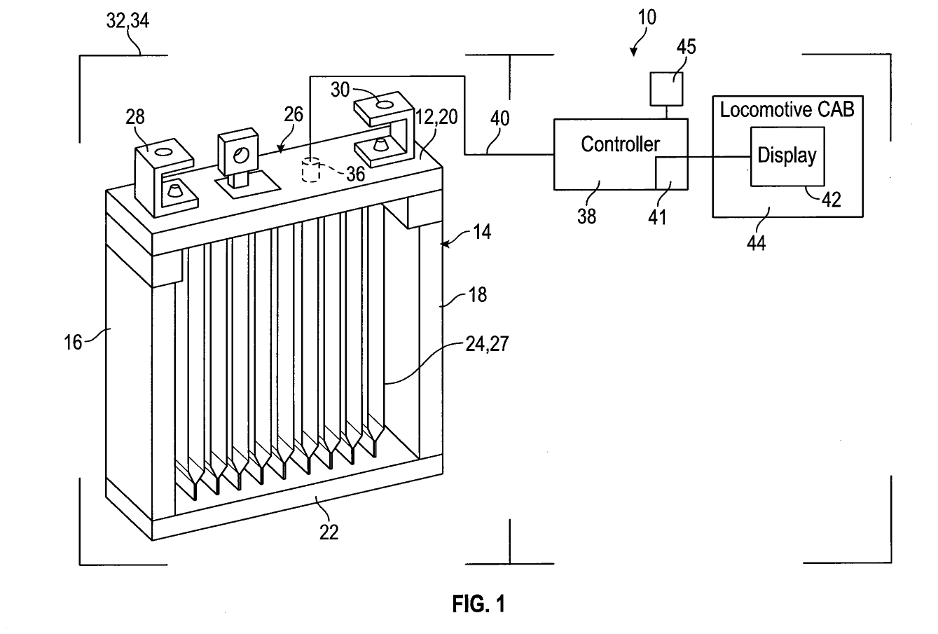

As shown in FIG. 1, a system, generally designated 10, is used to monitor the useful life of an insulation component 12 of a resistor 14, which in the embodiment shown takes the form of a dynamic braking resistor. In an exemplary embodiment, the resistor 14 includes a pair of flat, planar side walls 16, 18, flat, planar top and bottom walls 20, 22, respectively, and a plurality of flat, plate-shaped resistor elements 24. The side walls 16, 18 are oriented parallel to each other, as are the top and bottom walls 20, 22. The side walls 16, 18 and top and bottom walls 20, 22 are connected to form a frame 26. The resistor elements 24 are attached to, and extend between, the top and bottom walls 20, 22, respectively, within the frame 26, and are connected to each other in series. In embodiments, the resistor elements 24 are made into a continuous strip 27 that may be fan-folded such that the resistor elements 24 are parallel to each other. In other embodiments, the resistor elements 24 are plate-shaped and are welded or brazed to form the fan-folded, continuous strip 27.

The top wall 20 includes terminals 28, 30 that are connected to the ends of the strip 27 of resistor elements 24, and may be connected to an electric motor/generator (not shown) of a diesel-electric locomotive 32, as part of a rheostatic braking system of the locomotive. The braking resistor 14 may be located in the engine compartment 34 of the locomotive 32 and may be cooled by fans (not shown) that blow cooling air through the frame 26 across and between the resistor elements 24.

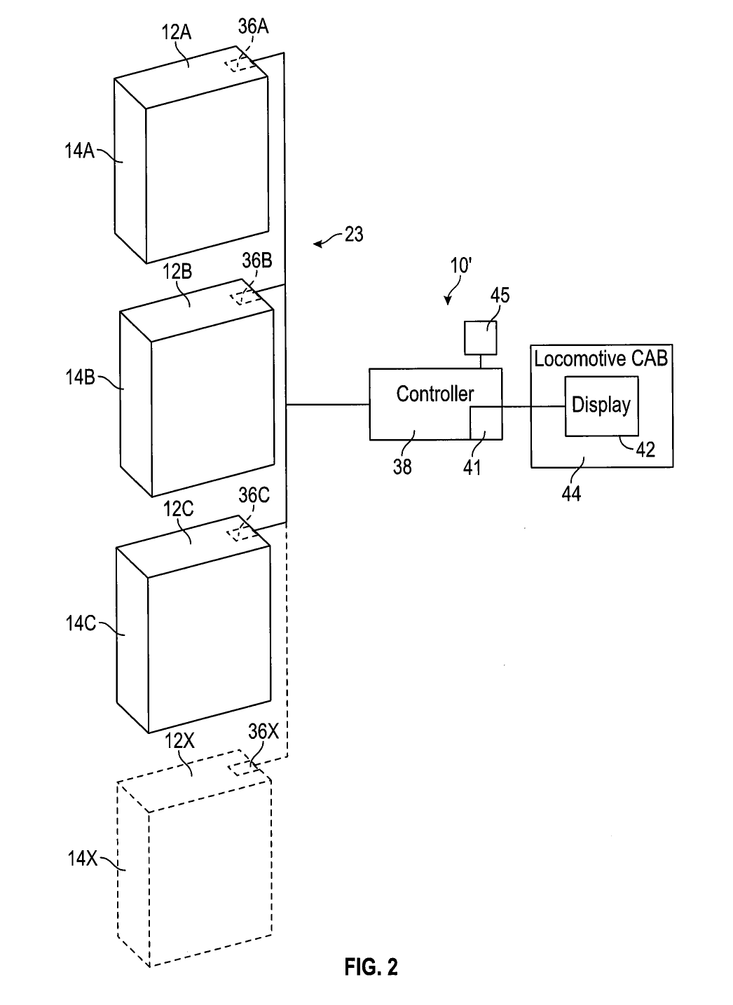

The side walls 16, 18, and top and bottom walls 20, 22 are attached to each other by fasteners such as screws (not shown) to form a rectangular frame 26. It is within the scope of the invention to utilize the system 10 with resistors 14 having different shapes, with frames that may be square or round. In an exemplary embodiment, the frame 26 may be made of molded insulation, such as a resin impregnated with fiberglass. The resistor elements 24 are retained within slots formed in the inside surfaces of the top and bottom walls 20, 22, respectively. As shown in FIG. 2, the system 10′ may be used with a plurality of resistors 14A, 14B, 14C, . . . 14X making up a dynamic braking grid 23, each resistor having a corresponding insulation component 12A, 12B, 12C, . . . 12X, respectively. In exemplary embodiments, configurations of braking resistors 14 include a metal casing outside of the insulation component 12 and may not have insulation on all sides of the frame 26.

Referring back to FIG. 1, the system 10 includes a sensor 36 that is embedded below an outer surface of the insulation component 12 of the frame 26 to measure the temperature of the insulation component. Although the sensor 36 is shown embedded in the top wall 20 of the frame 26, in other embodiments, the sensor 36 is embedded in one of the side walls 16, 18, or the bottom wall 22. The sensor 36 may take the form of a thermocouple, a thermistor, or any other probe suitable for measuring temperature. In embodiments, the sensor 36 is embedded below the outer surface of the insulation component 12 in order to protect the sensor from the corrosive environment of the engine compartment 34 or other location of the locomotive 32 where the resistor 14 is mounted. The resistor 14 may be located in different areas of the locomotive 32. For example, resistor 14 may be located above the engine compartment 34 rather than within it.

The system 10 includes a controller 38 that is connected to receive a signal from the sensor 36 indicative of the measured temperature of the insulation component 12. The controller 38 may be connected to the sensor 36 by wire or cable 40, or in other embodiments the connection may be wireless, as by Wi-Fi, Z-Wave, Bluetooth, or other data communication technology, or integrated into the controller area network (CAN) of the locomotive 32. The controller 38 is programmed to compare the temperature measured by the sensor 36 of the insulation component 12 to a predetermined threshold activation temperature for the insulation component, and decrement from a predetermined useful life value for the insulation component a life depreciation value assigned to the measured temperature to arrive at and determine a remaining life value of the insulation component, if the measured temperature of the insulation component is greater than the threshold activation temperature. In embodiments, the controller 38 is programmed to add a factor to the temperature measured by the sensor 36, which is embedded in the insulation component 12, to arrive at a temperature of the surface (e.g., the outer or upper surface) of the insulation component in which it is embedded. In embodiments, the controller 38 then compares the remaining life value to a predetermined end-of-life value for the insulation component, and generates a warning signal if the remaining life value is at or below the predetermined end-of-life value.

The system 10 may include a data store 41, which may include non-volatile memory, connected to or integral with the controller 38. In other exemplary embodiments, the data store 41 may consist of or include storage physically remote from the controller 38 and/or the locomotive 32, and may include or take the form of cloud storage. The data store 41 contains stored values for some or all of the predetermined threshold activation temperature for the insulation component 12, the predetermined useful life value, the predetermined end-of-life value, the life depreciation values assigned to the temperatures measured by the sensor 36, the upper temperature warning limit, and the calculated remaining life value. These values may be contained in a lookup table stored in the data store 41. The values may be selected and/or developed in a manner described below.

The data store 41 also may include a plurality of stored life depreciation values. Each life depreciation value of the plurality of stored life depreciation values corresponds to a different one of a plurality of temperatures, each greater than the threshold activation temperature, that may be measured by the sensor 36. The controller 38 also may be programmed to compare a second subsequent measured temperature of the insulation component 12, taken after a predetermined time interval, such as between 1 and 5 seconds, to the predetermined threshold activation temperature, and decrement from the remaining life value the life depreciation value from the plurality of stored life depreciation values assigned to the second subsequent measured temperature, to determine a second remaining life value of the insulation component, if the measured temperature of the insulation component is greater than the threshold activation temperature. The controller 38 then compares the second remaining life value to the end-of-life value, and generate a warning signal if the second remaining life value is at or below the predetermined end-of-life value.

The controller 38 may be programmed, at predetermined time intervals during operation of the resistor 14, such as 1 second to 5 second intervals, to compare a subsequent temperature of the insulation component 12 measured by the sensor 36 to a predetermined threshold activation temperature for the insulation component, decrement from the remaining life value a life depreciation value assigned to the subsequent measured temperature to determine a subsequent remaining life value if the measured temperature of the insulation component is greater than the threshold activation temperature, compare the subsequent remaining life value to the end-of-life value, and generate a warning signal or alarm if the subsequent remaining life value is at or below the predetermined end-of-life value.

As shown in FIG. 2, the system 10′ may include a plurality of sensors 36A, 36B, 36C, . . . 36X, wherein each sensor is embedded in an insulation component 12A, 12B, 12C, . . . 12X respectively, of resistors 14A, 14B, 14C, . . . 14X, respectively. In exemplary embodiments, the system 10′ may include a fewer or greater number of sensors 36 and resistors 14 comprising the braking grid 23. Also in embodiments, the system 10′ may include more than one sensor 36 in a resistor 14. With such embodiments, the controller 38 is connected to receive a signal from each of the plurality of sensors 36A-36X indicative of a measured temperature of an associated insulation component 12A-12X. The controller may be programmed to read the plurality of sensors 36A-36X sequentially.

For each of the plurality of sensors 36A-36X, the controller 38 is programmed to compare the measured temperature of the associated insulation component 12 to a predetermined threshold activation temperature for the associated insulation component, decrement from a predetermined useful life value for the associated insulation component a life depreciation value assigned to the measured temperature to determine a remaining life value of the insulation component, if the measured temperature of the insulation component is greater than the threshold activation temperature, compare the remaining life value to an end-of-life value for the associated insulation component, and generate a warning signal if the remaining life value is at or below the predetermined end-of-life value for the associated insulation component. The predetermined useful life value, end-of-life value, threshold activation temperature, and life depreciation values corresponding to temperatures measured by the sensors 36 may vary from one to another of the resistors 14A-14X, depending upon the composition of the insulation component 12A-12X and construction of the resistors.

The system 10, 10′ also may include a display 42 connected to the controller 38 to receive and display the warning signal. The display 42 may be located in the locomotive cab 44. the controller 38 also may be programmed to display in real time the remaining life value of one or more of the braking resistor grids 14A-14X, when queried by an operator of the locomotive 32. In other embodiments the controller 38 may incorporate, or be connected to, a transmitter 45 so that data indicative of real-time remaining life values, temperatures, and warning and shutdown flag conditions of one or more of the braking resistors 14A-14X may be read and/or stored remotely. This data may be used to schedule maintenance of the locomotive 32 at a convenient time and location.

The controller 38 may be programmed to read a signal from a selected sensor 36 of the plurality of sensors 36A-36X indicative of a temperature sensed by the selected sensor, compare the sensed temperature to a set point temperature stored in the data store 41, and if the sensed temperature is at or greater than the stored set point temperature, activate the system 10, 10′.

### Developing the Useful Life Value and Depreciation Values

In an exemplary embodiment, a process for developing the values for the lookup table stored in the data store 41 of the controller 38, which are used in the useful life value calculation and in selecting the depreciation values for the insulation component 12 that is monitored by the system 10, 10′ is as follows. Initially, the known or predetermined end-of-life value for the specific material to be monitored, which in embodiments is the insulation component 12, is determined. This requires determining the critical physical and electrical properties of the material for the application, made by performing end-of-life testing using industry standard methods, such as those published by ASTM International. For example, with a braking resistor frame made of fiberglass impregnated resin, end-of-life occurs when the strength of the frame material is reduced by one-half. This testing is conducted at multiple temperatures for each relevant property of the frame material, such as the strength and the surface condition of the insulation component 12.

Next, equations are developed to calculate the depreciation values from a given time and temperature. Failure time versus temperature for each property is plotted, and the Arrhenius equation is used if necessary to bridge gaps and/or extend the developed data set. The best fit equation(s) for the data set is/are determined. Multiple equation types are analyzed, and expected values are compared to actual values. This may be effected using a spreadsheet program such as Excel. All failure data is combined into a common table and plotted. The Arrhenius equation is employed if necessary to bridge gaps and/or extend the developed data set.

These developed equations are applied to a table of failure data. The expected value versus the calculated values at known and projected points are analyzed, and the best fit equation(s) based on this analysis are determined. In embodiments, the data is analyzed in ranges, as it is expected that mathematical models of material degradation will change as temperatures become more elevated.

A data table is created by utilizing the developed equations to calculate life expectancy, in hours, for each realistic temperature point for the tested material. This value is converted to seconds and then inverted, creating a decimal number representing the portion of useful life of the tested material consumed in one second at a given temperature. This value is multiplied by the sampling rate. Multiple factors may be considered regarding determining the sampling rate, including application and processing capability of the controller 38.

The number or value that will represent 100% of the useful life of the material in the algorithm is selected. The useful life value is a number that should be optimized with regard to calculation precision and processor capability of the controller 38. The results of the product of sampling rate and value of the portion of useful life of the tested material consumed in one second at the given temperature are multiplied by the total useful life, which yields the table value for each temperature point. The following Table 1 shows the values developed for the insulation component 12, which in embodiments is a fiberglass-impregnated resin insulation component, for the frame 26 of the braking resistor 14 of FIG. 1 using this process. The values represent the portion of degradation of insulation component 12 of the braking resistor 14 for two seconds at a given temperature, taken from a threshold or set point temperature of 60° C. to a maximum temperature of 263° C., in 1° C. increments.

TABLE 1

| | Portion of |
|---|---|
| T ° C. | 1 × 10¹⁴ Life |
| 263 | 4113033995 |
| 262 | 3824535634 |
| 261 | 3555284386 |
| 260 | 3304062647 |
| 259 | 3069725605 |
| 258 | 2851197143 |
| 257 | 2647465960 |
| 256 | 2457581891 |
| 255 | 2280652434 |
| 254 | 2115839452 |
| 253 | 1962356055 |
| 252 | 1819463652 |
| 251 | 1686469159 |
| 250 | 1562722359 |
| 249 | 1447613406 |
| 248 | 1340570466 |
| 247 | 1241057485 |
| 246 | 1148572080 |
| 245 | 1062643551 |
| 244 | 982830997 |
| 243 | 908721542 |
| 242 | 839928653 |
| 241 | 776090564 |
| 240 | 716868776 |
| 239 | 661946651 |
| 238 | 611028082 |
| 237 | 563836239 |
| 236 | 520112387 |
| 235 | 479614772 |
| 234 | 442117574 |
| 233 | 407409914 |
| 232 | 375294925 |
| 231 | 345588877 |
| 230 | 318120349 |
| 229 | 292729451 |
| 228 | 269267098 |
| 227 | 247594318 |
| 226 | 227581609 |
| 225 | 209108329 |
| 224 | 192062125 |
| 223 | 176338400 |
| 222 | 155440887 |
| 221 | 137181470 |
| 220 | 124419744 |
| 219 | 114864476 |
| 218 | 107239375 |
| 217 | 100766983 |
| 216 | 94946195 |
| 215 | 89448385 |
| 214 | 84065758 |
| 213 | 78682866 |
| 212 | 73257196 |
| 211 | 67801995 |
| 210 | 62368882 |
| 209 | 57030515 |
| 208 | 51864938 |
| 207 | 46943341 |
| 206 | 42322189 |
| 205 | 38039686 |
| 204 | 34115732 |
| 203 | 30554180 |
| 202 | 27346228 |
| 201 | 24474048 |
| 200 | 21914093 |
| 199 | 19639801 |
| 198 | 17623645 |
| 197 | 15838558 |
| 196 | 14258855 |
| 195 | 12860769 |
| 194 | 11622697 |
| 193 | 10525266 |
| 192 | 9551269 |
| 191 | 8685529 |
| 190 | 7914731 |
| 189 | 7227229 |
| 188 | 6612868 |
| 187 | 6062799 |
| 186 | 5569320 |
| 185 | 5125728 |
| 184 | 4726184 |
| 183 | 4365602 |
| 182 | 4039545 |
| 181 | 3744138 |
| 180 | 3475993 |
| 179 | 3232142 |
| 178 | 3009981 |
| 177 | 2807221 |
| 176 | 2621849 |
| 175 | 2452088 |
| 174 | 2296369 |
| 173 | 2153303 |
| 172 | 2021657 |
| 171 | 1900338 |
| 170 | 1788373 |
| 169 | 1684894 |
| 168 | 1589125 |
| 167 | 1500374 |
| 166 | 1418019 |
| 165 | 1341504 |
| 164 | 1270327 |
| 163 | 1204036 |
| 162 | 1142226 |
| 161 | 1084528 |
| 160 | 1030611 |
| 159 | 980173 |
| 158 | 932940 |
| 157 | 888666 |
| 156 | 847125 |
| 155 | 808110 |
| 154 | 771434 |
| 153 | 736927 |
| 152 | 704432 |
| 151 | 673805 |
| 150 | 644915 |
| 149 | 617641 |
| 148 | 591874 |
| 147 | 567511 |
| 146 | 544459 |
| 145 | 522630 |
| 144 | 501946 |
| 143 | 482333 |
| 142 | 463723 |
| 141 | 446053 |
| 140 | 429265 |
| 139 | 413305 |
| 138 | 398122 |
| 137 | 383670 |
| 136 | 369906 |
| 135 | 356790 |
| 134 | 344283 |
| 133 | 332352 |
| 132 | 320964 |
| 131 | 310088 |
| 130 | 299696 |
| 129 | 289761 |
| 128 | 280259 |
| 127 | 271166 |
| 126 | 262461 |
| 125 | 254124 |
| 124 | 246134 |
| 123 | 238475 |
| 122 | 231130 |
| 121 | 224082 |
| 120 | 217317 |
| 119 | 210821 |
| 118 | 204580 |
| 117 | 198582 |
| 116 | 192816 |
| 115 | 187271 |
| 114 | 181935 |
| 113 | 176800 |
| 112 | 171856 |
| 111 | 167094 |
| 110 | 162505 |
| 109 | 158083 |
| 108 | 153820 |
| 107 | 149708 |
| 106 | 145741 |
| 105 | 141912 |
| 104 | 138217 |
| 103 | 134648 |
| 102 | 131201 |
| 101 | 127870 |
| 100 | 124650 |
| 99 | 121538 |
| 98 | 118528 |
| 97 | 115617 |
| 96 | 112800 |
| 95 | 110074 |
| 94 | 107434 |
| 93 | 104879 |
| 92 | 102403 |
| 91 | 100005 |
| 90 | 97680 |
| 89 | 95428 |
| 88 | 93243 |
| 87 | 91125 |
| 86 | 89071 |
| 85 | 87077 |
| 84 | 85143 |
| 83 | 83265 |
| 82 | 81442 |
| 81 | 79672 |
| 80 | 77953 |
| 79 | 76283 |
| 78 | 74660 |
| 77 | 73083 |
| 76 | 71549 |
| 75 | 70059 |
| 74 | 68609 |
| 73 | 67199 |
| 72 | 65827 |
| 71 | 64493 |
| 70 | 63194 |
| 69 | 61930 |
| 68 | 60699 |
| 67 | 59501 |
| 66 | 58334 |
| 65 | 57197 |
| 64 | 56089 |
| 63 | 55010 |
| 62 | 53959 |
| 61 | 52934 |
| 60 | 51934 |

For this material, a useful life number is selected to be 10¹⁴ units, and each temperature exposure is associated with a number that is selected to represent a value in units to be subtracted from that useful life number for a two-second exposure. For example, using Table 1, if the insulation component 12 is subjected to a temperature of 249° C. for one second, the controller 38 reduces the useful life value of the insulation component by 1447613406. Thus, 10¹⁴−1447613406=0.99998552386594×10¹⁴, which is the remaining useful life value for that insulation component 12 after that time and temperature exposure. The controller 38 then stores that new useful life number in data store 41 and/or displays that value, or a corresponding value, which may be expressed as a percentage, or as a color (e.g., green, yellow, or red for proximity to the end-of-life value) on the display 42 in the locomotive cab 44. As will be explained in greater detail below, this process of decrementing the current useful or remaining life value by a value corresponding to a measured temperature of the insulation component 12 is performed continuously during operation of the system 10, 10′.

### Monitoring Method

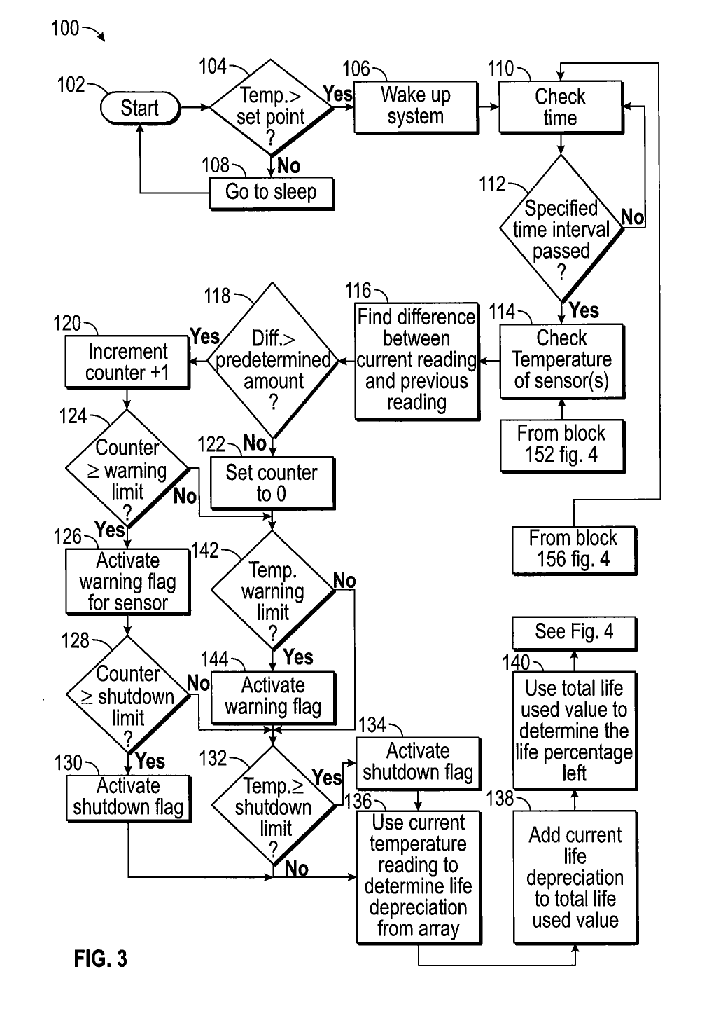

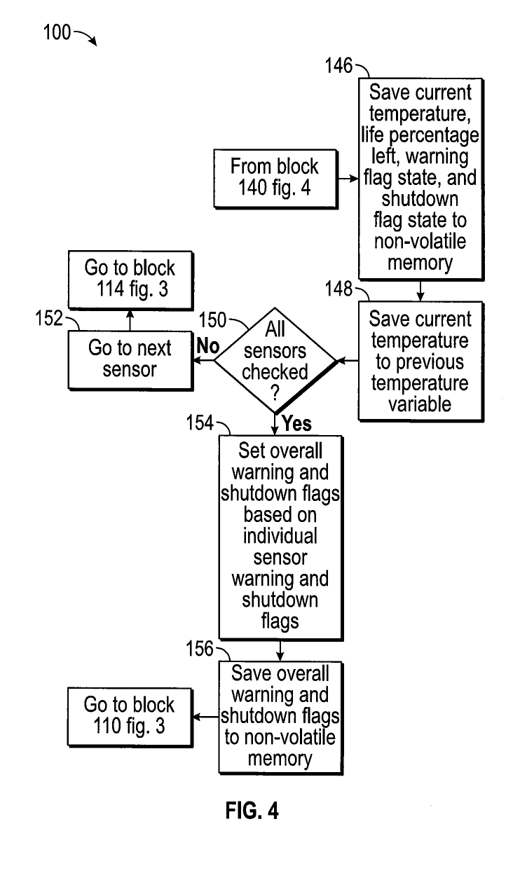

As shown in FIGS. 3 and 4, a method for monitoring a useful life of an insulation component 12 of a braking resistor 14, or an insulation component 12A-12X of braking resistor grid 23, which in an exemplary embodiment utilizes the systems 10, 10′ of FIGS. 1 and 2, is illustrated in a flowchart generally designated 100. The method begins with the controller 38 measuring the temperature of the insulation component 12 with the sensor 36, as indicated in block 102, by receiving a signal from the sensor indicative of a temperature of the insulation component. As indicated in block 104, if the temperature measured by the sensor 36 is greater than a preselected set point or activation temperature, such as 60° C., the system 10, 10′ “wakes up” or is activated, as indicated in block 106. If the temperature is below the set point temperature, as indicated in block 108, the system is not activated, or “goes to sleep.” The set point temperature is selected using the previously described method such that below the set point temperature there is no effective thermal degradation of the insulation component 12 over time. Alternatively, the system 10, 10′ does not “sleep,” but the controller 38 does not go through the remaining steps of the flowchart 100 unless the temperature measured by the sensor 36 rises above the set point temperature.

As shown in block 110, the time of day is checked, and as indicated in decision diamond 112, if a specified or preselected time interval has elapsed since the last time measurement, such as between 1 to 5 seconds, the temperature measured by the sensor 36 is checked and stored in data store 41, as indicated in block 114. If not, the process loops back to the time check block 110. If the controller 38 checks the temperature of the sensor 36 (or sensors 36A-36X), the controller calculates the difference between the current temperature reading and the previous reading, as indicated in block 116. As indicated in decision diamond 118, if the temperature difference for that time interval is greater than a predetermined amount, e.g., 5° C., the controller 38 increments an internal counter, as indicated at block 120. If the calculated temperature increase is less than the predetermined amount for the time interval, the counter is set to 0, as indicated in block 122.

As indicated at decision diamond 124, if the counts recorded by the counter equal or exceed a predetermined or pre-set value, such as 5 (i.e., 5 consecutive time intervals of at least a 5° C. temperature increase of the insulation component 12), which has been preselected as an unacceptably rapid rate of increase of the temperature of the insulation component, the controller 38 activates a warning flag, indicated in block 126, for the measured sensor 36. The warning flag may take the form of a visual alert displayed on display 42 within the locomotive cab 44 of the locomotive 32, and/or may take the form of an audible alarm. Next, as indicated in decision diamond 128, if the counter value meets or exceeds a predetermined shutdown limit, the controller 38 activates a shutdown flag, as indicated in block 130, which may take the form of a shutdown alert displayed on display 42. The warnings and/or temperature data also may be transmitted by transmitter 45 to a remote station (not shown).

Alternatively, if the counter value is less than the predetermined shutdown limit, then as indicated in decision diamond 132, the controller 38 determines whether the measured temperature is greater than or equal to an upper temperature limit or a shutdown temperature limit for the resistor 14 associated with the sensor 36, such as 316° C. (600° F.). If the measured temperature is greater than or equal to the shutdown temperature limit, then as indicated in block 134, the controller activates a shutdown flag, which may take the form of a shutdown notification shown on display 42. Consequently, the operator, and/or the controller 38, of the locomotive may shut off current flow to the resistor 14, and/or apply alternative braking means such as a friction brake.

Whether or not the measured temperature of the insulation component 12 is less than the shutdown limit temperature, as indicated in block 136 the controller uses the lookup table stored in data store 41, such as Table 1 supra, to determine a braking resistor life depreciation value for that measured temperature from the array, and as indicated in block 138, the controller 38 adds that life depreciation value (i.e., decrements the useful life value) to the stored life used value for that braking resistor, if any. As indicated in block 140, the controller 38 uses the new stored life used value to determine the percentage of life left in the insulation component, and hence the braking resistor.

Alternatively, referring to block 122, if the counter is reset by the controller 38 to 0, the controller then determines whether the temperature is at or above the warning limit, as shown in decision diamond 142, and if so, as shown in block 144, the controller activates the warning flag, which may take the form of an alert displayed on display 42. In either case, the controller 38 determines whether the temperature measured by the sensor 36 is at or greater than the shutdown limit, as indicated in decision diamond 132. The process proceeds from decision diamond 132 as described above.

As shown in FIG. 4, after the life percentage left, which may be expressed as a remainder number as described above, is calculated by the controller 36 as indicated in block 140 (FIG. 3), then as indicated in block 146, the controller saves in non-volatile memory in the data store 41 the current temperature measured by the sensor, the life percentage of the insulation component 12 left, the warning flag state (off or activated), and the shutdown flag state (off or activated). The controller 38 then saves the current temperature of the insulation component 12 to the previous temperature variable; that is, the previous temperature reading in block 116 (Fig. 3) is overwritten with a second subsequent measured temperature, which is the current measured temperature, as indicated in block 148.

As indicated in decision diamond 150, the controller 38 then determines whether all sensors 36A-36X (FIG. 2) have been checked. If not, as indicated in block 152, the controller 38 proceeds to read (check) the temperature of the next sensor, as indicated in block 114, and the process proceeds for that sensor as described above. If all sensors 36A-36X have been checked, then, as indicated in block 154, the controller 38 sets overall warning and shutdown flags for the system of resistor grids 14A-14X based on the warning and shutdown flags for individual sensor 36A-36X readings. In this way, the overall system may be shut down if only one or more of the sensors 36A-36X detect temperatures of their respective insulation components 12A-12X at or above the aforementioned preset threshold activation temperatures.

And finally, as indicated in block 156, the controller 38 saves the overall warning and shutdown flag states to nonvolatile memory in the data store 41. The controller 38 then begins the process again, checking the time of day, as indicated in block 110 (FIG. 3) and reading a next or subsequent measured temperature of the sensors 36A-36X.

The foregoing process, which is illustrated schematically in FIGS. 3 and 4, includes routines for determining whether the measured temperature of the insulation component has exceeded a preset or predetermined upper limit temperature, in which case warning and/or shutdown flags are generated by the controller 38. However, in an exemplary embodiment, the method for monitoring the useful life of an insulation component 12 of a braking resistor 14 may be performed without, or separate from, the warning and shutdown routines.

That method begins with measuring the temperature of the insulation component 12 by the sensor 36, and receiving a signal from the sensor indicative of the temperature of the insulation component by the controller 38. The controller 38 compares the measured temperature of the insulation component 12 to a predetermined threshold activation temperature for the insulation component, then decrements from the predetermined useful life value for the insulation component a life depreciation value assigned to the measured temperature to determine a remaining life value of the insulation component if the measured temperature of the insulation component is greater than the threshold activation temperature. The controller 38 then compares the remaining life value to the end-of-life value for the insulation component 12 and generates a warning signal, which may be displayed on the display 42, if the remaining life value is at or below the predetermined end-of-life value.

In performing this method, the controller 38 stores in the data store 41 values for the predetermined threshold activation temperature for the insulation component, the predetermined useful life value, the predetermined end-of-life value, the life depreciation value assigned to the measured temperature, and the remaining life value. If the system 10′ is used with a plurality of sensors 36A-36X, the controller 38 stores in the data store 41 a plurality of stored life depreciation values, each life depreciation value of the plurality of stored life depreciation values corresponding to a different one of the plurality of temperatures greater than the predetermined threshold activation temperature (e.g., 60° C.) for the insulation component 12.

During the next subsequent iteration of the method, the controller 38 compares a second subsequent temperature, measured by the sensor 36, of the insulation component 12 to the predetermined threshold activation temperature, decrements from the remaining life value the life depreciation value from the plurality of stored life depreciation values assigned to the second measured temperature to determine a second remaining life value of the insulation component, if the measured temperature of the insulation component is greater than the threshold activation temperature. The controller 38 then compares the second remaining life value to the end-of-life value, and generates a warning signal if the second remaining life value is at or below the predetermined end-of-life value.

With this method the controller 38 compares, at predetermined time intervals during operation of the braking resistor 14, a subsequent measured temperature of the insulation component to the predetermined threshold activation temperature for the insulation component, and decrements from the remaining life value a life depreciation value assigned to the subsequent measured temperature to determine a subsequent remaining life value if the measured temperature of the insulation component is greater than the threshold activation temperature. The controller 38 then compares the subsequent remaining life value to the end-of-life value, and generates a warning signal if the subsequent remaining life value is at or below the predetermined end-of-life value.

As discussed previously, in exemplary embodiments the method begins by embedding a plurality of sensors 36A-36X in the insulation components 12A-12X, of different resistors 14A-14X and connecting the plurality of sensors to the controller 38. The process then proceeds with the controller 38 receiving a signal from each of the plurality of sensors 36A-36X indicative of a measured temperature of an associated insulation component 12A-12X. For each of the plurality of sensors 12A-12X, the controller 38 compares the measured temperature of the associated insulation component to a predetermined threshold activation temperature for the associated insulation component, decrements from a predetermined useful life value for the associated insulation component a life depreciation value assigned to the measured temperature to determine a remaining life value of the insulation component if the measured temperature of the insulation component is greater than the threshold activation temperature, compares the remaining life value to an end-of-life value for the associated insulation component, and generates a warning signal if the remaining life value is at or below the predetermined end-of-life value for the associated insulation component.

The warning signal may be displayed on a display 42 connected to the controller 38. The plurality of sensors 12A-12X may be embedded below outer surfaces of the insulation components 12A-12X of a plurality of different braking resistors 14A-14X. In such case the controller 38 sequentially reads signals from the plurality of sensors 36A-36X.

In another exemplary embodiment, the foregoing system 10, 10′ and method 100 may be employed with a test object other than the insulation component 12, such as transformer and electrical contactor components, including insulation. In such other applications, the system 10, 10′ is arranged as shown in FIGS. 1 and 2, wherein the insulation component 12, 12A-12X represents the test object, including one of the forgoing specified test objects. The system 10, 10′ includes a sensor 36 that is attached to the test object 12 to measure a temperature of the test object; and a controller 38 is connected to receive a signal from the sensor indicative of the measured temperature of the test object. The controller 38 is programmed to compare the measured temperature of the test object 12 to a predetermined threshold activation temperature for the test object, decrement from a predetermined useful life value for the test object a life depreciation value assigned to the measured temperature to determine a remaining life value of the test object if the measured temperature of the insulation component is greater than the threshold activation temperature, compare the remaining life value to a predetermined end-of-life value for the test object, and generate a warning signal or alarm if the remaining life value is at or below the predetermined end-of-life value for the test object.

The disclosed system and method for monitoring resistor life provides a low-cost, retrofittable, and robust solution to facilitate efficient scheduling of braking grid resistors, and other components that degrade over time in response to exposure to high temperatures. While the forms of apparatus and methods described herein are preferred embodiments of the disclosed system and method for monitoring resistor life, it should be understood that the invention is not limited to these precise embodiments, and that changes may be made therein without departing from the scope of the invention.

What is claimed is:

1. A system for monitoring a useful life of an insulation component of a braking resistor, the system comprising:
a sensor that can be embedded below an outer surface of the insulation component to measure a temperature of the insulation component; and
a controller connected to receive a signal from the sensor indicative of the measured temperature of the insulation component, and programmed to compare the measured temperature of the insulation component to a predetermined threshold activation temperature for the insulation component, decrement from a predetermined useful life value for the insulation component a life depreciation value assigned to the measured temperature to determine a remaining life value of the insulation component if the measured temperature of the insulation component is greater than the threshold activation temperature, compare the remaining life value to a predetermined end-of-life value for the insulation component, and generate a warning signal if the remaining life value is at or below the predetermined end-of-life value.

2. The system of claim 1, further comprising a data store connected to the controller, the data store containing stored values for the predetermined threshold activation temperature for the insulation component, the predetermined useful life value, the predetermined end-of-life value, the life depreciation value assigned to the measured temperature, and the remaining life value.

3. The system of claim 2, wherein the data store includes a plurality of stored life depreciation values, each life depreciation value of the plurality of stored life depreciation values corresponding to a different one of a plurality of temperatures greater than the activation temperature that can be measured by the sensor.

4. The system of claim 3, wherein the controller is programmed to compare a second subsequent measured temperature of the insulation component to the predetermined threshold activation temperature, decrement from the remaining life value the life depreciation value from the plurality of stored life depreciation values assigned to the second subsequent measured temperature to determine a second remaining life value of the insulation component if the measured temperature of the insulation component is greater than the threshold activation temperature, compare the second remaining life value to the predetermined end-of-life value, and generate a warning signal if the second remaining life value is at or below the predetermined end-of-life value.

5. The system of claim 1, wherein the controller is programmed to perform, at predetermined time intervals during operation of the resistor, comparing a subsequent measured temperature of the insulation component to a predetermined threshold activation temperature for the insulation component, decrementing from the remaining life value a life depreciation value assigned to the subsequent measured temperature to determine a subsequent remaining life value if the measured temperature of the insulation component is greater than the threshold activation temperature, comparing the subsequent remaining life value to the end-of-life value, and generate a warning signal if the subsequent remaining life value is at or below the predetermined end-of-life value.

6. The system of claim 5, wherein the predetermined time intervals are selected from one second to five seconds.

7. The system of claim 1, further comprising a plurality of sensors, wherein each sensor can be embedded in an insulation component of a different braking resistor; wherein the controller is connected to receive a signal from each of the plurality of sensors indicative of a measured temperature of an associated insulation component; and for each of the plurality of sensors, the controller is programmed to compare the measured temperature of the associated insulation component to a predetermined threshold activation temperature for the associated insulation component, decrement from a predetermined useful life value for the associated insulation component a life depreciation value assigned to the measured temperature to determine a remaining life value of the insulation component if the measured temperature of the insulation component is greater than the threshold activation temperature, compare the remaining life value to an end-of-life value for the associated insulation component, and generate a warning signal if the remaining life value is at or below the predetermined end-of-life value for the associated insulation component.

8. The system of claim 1, further comprising a display connected to the controller to receive and display the warning signal.

9. The system of claim 8, wherein the display is located in a locomotive engine cab.

10. The system of claim 1, further comprising a plurality of sensors that can be embedded below outer surfaces of insulation components of a plurality of different braking resistors, and wherein the controller is programmed to sequentially read signals from the plurality of sensors.

11. The system of claim 10, wherein the controller is programmed to read a signal from a selected sensor of the plurality of sensors indicative of a sensed temperature from the selected sensor, compare the measured temperature to a stored set point temperature, and if the measured temperature is at or greater than the stored set point temperature, activate the system.

12. A method for monitoring a useful life of an insulation component of a braking resistor, the method comprising:
measuring a temperature of the insulation component by a sensor;
receiving a signal from the sensor indicative of a temperature of the insulation component by a controller;
comparing by the controller the measured temperature of the insulation component to a predetermined threshold activation temperature for the insulation component, decrementing from a predetermined useful life value for the insulation component a life depreciation value assigned to the measured temperature to determine a remaining life value of the insulation component if the measured temperature of the insulation component is greater than the threshold activation temperature, comparing the remaining life value to a predetermined end-of-life value for the insulation component; and
generating a warning signal if the remaining life value is at or below the predetermined end-of-life value.

13. The method of claim 12, further comprising storing in a data store values for the predetermined threshold activation temperature for the insulation component, the predetermined useful life value, the predetermined end-of-life value, the life depreciation value assigned to the measured temperature, and the remaining life value.

14. The method of claim 12, further comprising storing in a data store a plurality of stored life depreciation values, each life depreciation value of the plurality of stored life depreciation values corresponding to a different one of a plurality of temperatures greater than the predetermined threshold activation temperature for the insulation component.

15. The method of claim 14, further comprising comparing by the controller a second subsequent measured temperature of the insulation component to the predetermined threshold activation temperature, decrementing from the remaining life value the life depreciation value from the plurality of stored life depreciation values assigned to the second subsequent measured temperature to determine a second remaining life value of the insulation component if the measured temperature of the insulation component is greater than the threshold activation temperature, comparing the second remaining life value to the end-of-life value, and generating a warning signal if the second remaining life value is at or below the predetermined end-of-life value.

16. The method of claim 12, further comprising comparing by the controller, at predetermined time intervals during operation of the braking resistor, a subsequent measured temperature of the insulation component to a predetermined threshold activation temperature for the insulation component, decrementing from the remaining life value a life depreciation value assigned to the subsequent measured temperature to determine a subsequent remaining life value if the measured temperature of the insulation component is greater than the threshold activation temperature, comparing the subsequent remaining life value to the end-of-life value, and generating a warning signal if the subsequent remaining life value is at or below the predetermined end-of-life value.

17. The method of claim 12, further comprising embedding a plurality of sensors in the insulation component, of a different braking resistor; connecting the plurality of sensors to the controller; receiving by the controller a signal from each of the plurality of sensors indicative of a measured temperature of an associated insulation component; and for each of the plurality of sensors, comparing by the controller the measured temperature of the associated insulation component to a predetermined threshold activation temperature for the associated insulation component, decrementing from a predetermined useful life value for the associated insulation component a life depreciation value assigned to the measured temperature to determine a remaining life value of the insulation component if the measured temperature of the insulation component is greater than the threshold activation temperature, comparing the remaining life value to an end-of-life value for the associated insulation component, and generating a warning signal if the remaining life value is at or below the predetermined end-of-life value for the associated insulation component.

18. The method of claim 12, further comprising displaying the warning signal on a display connected to the controller.

19. The method of claim 12, further comprising embedding a plurality of sensors below outer surfaces of insulation components of a plurality of different braking resistors; and sequentially reading signals from the plurality of sensors by the controller.

20. A system for monitoring a useful life of a test object, the system comprising:
a sensor that can be attached to the test object to measure a temperature of a test object; and
a controller connected to receive a signal from the sensor indicative of the measured temperature of the test object, the controller programmed to compare the measured temperature of the test object to a predetermined threshold activation temperature for the test object, decrement from a predetermined useful life value for the test object a life depreciation value assigned to the measured temperature to determine a remaining life value of the test object if the measured temperature of the test object is greater than the threshold activation temperature, compare the remaining life value to a predetermined end-of-life value for the test object, and generate a warning signal if the remaining life value is at or below the predetermined end-of-life value for the test object.
